(19) United States
(12) Patent Application Publication
(10) Pub. No.: US 2010/0321046 A1
(43) Pub. Date: Dec. 23, 2010

(54) WIPEABLE CONDUCTIVITY PROBE AND METHOD OF MAKING SAME

(75) Inventors: Robert C. Randall, Westport, MA (US); Christopher J. Palassis, Yellow Springs, OH (US); Michael T. James, Dayton, OH (US); Edward E. King, Dayton, OH (US); Ben E. Barnett, Dayton, OH (US)

Correspondence Address: THOMPSON HINE L.L.P.;Intellectual Property Group, P.O. BOX 8801, DAYTON, OH, 45401-8801, US

(73) Assignee: YSI Incorporated, Yellow Springs, OH (US)

(21) Appl. No.: 12/814,520

(22) Filed: Jun. 14, 2010

Related U.S. Application Data
(60) Provisional application No. 61/187,768, filed on Jun. 17, 2009.

(51) Int. Cl. G01R 27/08; G01K 1/00; G01R 3/00

(52) U.S. Cl. 324/696; 374/100; 29/592.1

(57) ABSTRACT

A conductivity sensor is disclosed that comprises a forked electrode support that includes a first opposing arm and a second opposing arm spaced apart by a slot. Both the first arm and the second arm include a plurality of electrodes embedded in each arm. The first and second arms and the slot are capable of retaining a volume of fluid within the volume defined by the arms and the slot such that the conductivity of the fluid in the slot can be determined. The conductivity sensor is wipeable by a reciprocating wiper assembly positioned adjacent the forked electrode support such that the wiper element can travel through the slot and remove contaminants from the slot and the plurality of electrodes in each of the first and second arms. Also disclosed are methods of making the conductivity sensor.

### RELATED APPLICATIONS

The present application claims the priority benefit of U.S. provisional patent application Ser. No. 61/187,768, filed on Jun. 17, 2009, which is expressly incorporated by reference herein in its entirety.

### BACKGROUND

The present application relates to conductivity probes and more particularly to a wipeable conductivity probe for use in environmental water quality testing.

Fouling is a major problem on instruments used in long term submersion studies, such as oceanographic or other under water studies. These studies usually involve deploying multi-parameter devices for long periods of time (i.e., a year or more). The fouling, for example, may include the growth of algae or fungal slimes and grasses or hard shelled barnacles. One example of a water quality measurement device that employs a brush and wiper to wipe the probes is disclosed in commonly assigned U.S. Pat. No. 6,779,383.

Conductivity probes for use in water quality measurements have often been constructed from a small non-conductive tube having large flat electrodes at each end. The tube shape isolates a fluid volume that can enter the tube from either end. Based on the distance between the electrodes, the tube volume, and the measured resistance, the conductivity of a fluid in the tube can be determined. It will be apparent that the tubular design of these probes is not amenable to wiping. Over time, biological growth will occur within the tube and the conductivity measurements may no longer be reliable.

### SUMMARY

One aspect of the invention is a conductivity probe or sensor for use in environmental or water quality monitoring applications in which the probe isolates a volume of fluid but has an open construction that is accessible to wiping elements that can wipe organic foulants from the probe surfaces. The conductivity probe can be designed to be insertable into a water quality monitoring sonde as known in the art.

In one embodiment, the conductivity probe includes a forked electrode support. The forked electrode support being at an end of the conductivity probe. The forked electrode support includes first and second opposing arms or prongs that are separated by a slot and support a plurality of electrodes. In one embodiment, first and second electrodes are embedded in the first arm and third and fourth electrodes are embedded in the second arm. The first and second arms are designed so that they form an electrical conductivity cell by retaining a predetermined volume of fluid within the slot such that the conductivity of the fluid retained within the slot can be determined accurately. In one embodiment, the first electrode is a hollow cylindrical electrode and the second electrode is a rod electrode concentrically located within the first electrode and the third electrode is a hollow cylindrical electrode and the fourth electrode is a rod electrode concentrically located within the third electrode.

In another embodiment, the conductivity sensor is coupled with a reciprocating or rotating wiper assembly to form a wipeable conductivity sensor assembly. The wiper assembly includes a wiper element that travels through the slot in the forked electrode support and removes contaminants that form or accumulate in the slot that may affect the characteristics of the cell, more particularly, on the electrodes, the floor of the slot, and on the first and second arms.

Another aspect of the invention is a process of manufacturing the conductivity sensor, in particular, a process for making the forked electrode support and the opposing arm.

In one embodiment, the process includes providing a preform electrode element that is machineable to form two sets of concentric electrodes, which each comprise at least two concentric electrodes separated from one another by a gap to electrically insulate the electrodes, in which the alignment of portions that will form first and second electrodes relative to portions that will form third and fourth electrodes is fixed, encasing the preform electrode element in a plastic or ceramic material to form an encased preform electrode body, forming a slot in the encased preform electrode body by removing a portion of the plastic or ceramic material and a portion of the preform electrode element. The slot divides a portion of the encased preform electrode body into a first support and a secondsupport, wherein the first support includes a first set of concentric electrodes and the second support includes a second set of concentric electrodes that are aligned opposite one another to define a conductivity cell of a pre-determined volume.

The process may include surrounding the plastic member containing the preform electrode element with an outer housing. The outer housing can be a protective layer covering the electrode leads and may be made of an anti-fouling material.

In another embodiment, the process includes providing a first set of concentric electrodes and a second set of concentric electrodes and providing a forked electrode support that has first and second opposing arms spaced apart to provide a slot therebetween. The first opposing arm includes a first receptacle for receiving the first set of concentric electrodes and the second opposing arm includes a second receptacle for receiving the second set of concentric electrodes. The process includes placing the first and second sets of concentric electrodes into their respective receptacles and bonding the forked electrode support to each of the first and the second set of concentric electrodes with a watertight seal. This process may also include applying sealing glass to each mating surface of the first and second receptacles and the first and second set of concentric electrodes to seal the electrodes of each concentric electrode set to one another and to the forked electrode support when the electrode support is a ceramic material.

### BRIEF DESCRIPTION OF THE DRAWINGS

FIG. 1 is a perspective view of a novel conductivity sensor and a wiping mechanism.

FIG. 2 is a system diagram that shows various controllers and other devices that couple to the wipeable conductivity sensor assembly.

FIGS. 3-6 are side cross-sectional views of the electrode support of FIG. 1 taken along line 5-5 that illustrate different profiles for the floor of the slot.

FIG. 7 is a cross-sectional view of the electrode support of FIG. 1 taken along line 3-3 before the slot was formed.

FIG. 8 is a cross-sectional view of the electrode support of FIG. 1 taken along line 3-3 after the slot was formed in the electrode support.

FIG. 9 is a top view of the electrode support of FIG. 8.

FIGS. 10-11 are a side perspective view and a cross-sectional view of an embodiment of a preform electrode element.

FIGS. 12-13 are a side perspective view and a cross-sectional view of another embodiment of a preform electrode element.

FIGS. 14-15 are flow charts of embodiments of a process for manufacturing the forked electrode support.

FIG. 16 is a cross-sectional view of an alternate embodiment of a forked electrode support.

FIG. 17 is a flow chart of an embodiment of a method for manufacturing a forked electrode support.

FIGS. 18-19 are side perspective views of one embodiment of an electrode support.

FIG. 20 is a side perspective view of an alternate embodiment of the forked electrode support for a conductivity probe/sensor.

FIG. 21 is a cross-sectional view of the embodiment of FIG. 20 taken along line 21-21.

### DETAILED DESCRIPTION

The following detailed description will illustrate the general principles of the invention, examples of which are additionally illustrated in the accompanying drawings. In the drawings, like reference numbers indicate identical or functionally similar elements.

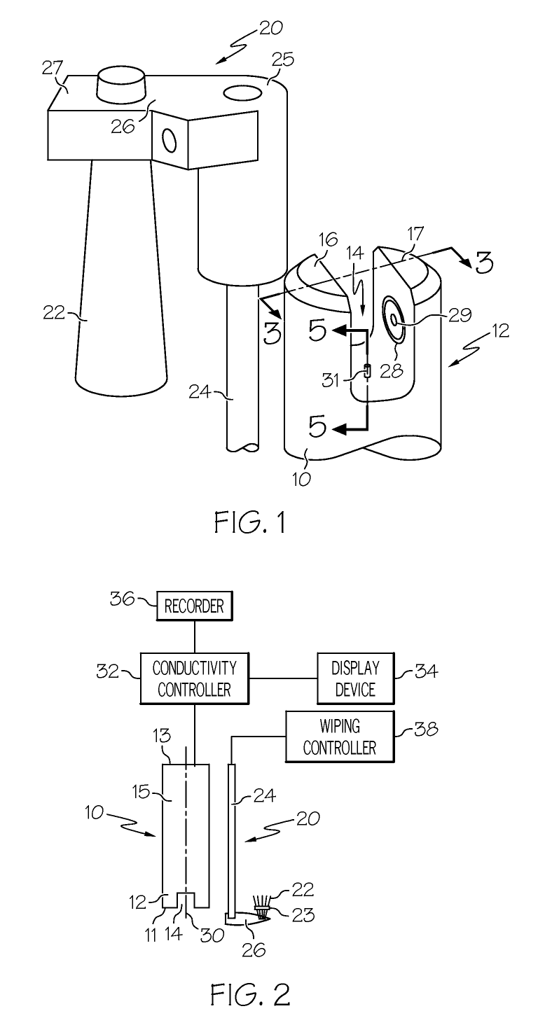

In one embodiment, as shown in FIGS. 1 and 2, a conductivity sensor 10 has a first end 11, a second end 13, an elongate housing 15, a central longitudinal axis 30, and includes a forked electrode support 12 that includes a slot 14 therein. The forked electrode support 12 defines the first end 11 of the conductivity sensor and includes a first electrode 18 and a second electrode 19 (best seen in FIG. 8) embedded in a first electrode arm or prong 16 adjacent the slot 14 and a third electrode 28 and fourth electrode 29 embedded in a second opposing electrode arm or prong 17 adjacent the slot 14. As shown in FIG. 1, the portion of the conductivity sensor 10 including the first and second electrode arms 16, 17 is generally cylindrical-shaped. In other embodiments, the portion of the conductivity sensor 10 including the first and second electrode arms 16, 17 may be a cuboid or any other rectilinear body or curvilinear shape.

The first and second electrodes 18, 19 together are a predetermined distance apart from the third and fourth electrodes 28, 29. The electrodes 18, 19, 28, 29 are used to measure the conductivity of a volume of fluid that is temporarily retained within slot 14 by applying a known AC voltage and observing the resultant AC current, which is proportional to the conductivity in the volume of fluid that is within the slot 14. The measured electrical conductivity is related to the effective path length (l) and the effective cross-sectional area (A) of the volume of fluid measured. The effective path length and area determine the cell constant (K) of the sensor: K=l/A. The cell constant determines the sensitivity of the sensor, and accordingly the specific electronic component values necessary to result in a certain circuit output signal for a given actual conductivity of the fluid. The apparent conductivity as seen by the circuit equals the actual conductivity of the fluid divided by K. Since temperature affects the conductivity measurement, a temperature probe 31 may be included in the electrode conductivity sensor 10. In FIG. 1 the temperature probe 31 is shown disposed within slot 14.

Slot 14 is wide enough and shaped to receive a wiper element 22 passing therethrough to remove debris from the slot 14 and/or the electrodes 18, 19, 28, 29, the arms 16, 17 and the floor 21 of the electrode support 12. Slot 14 needs to be kept free of foulants because the buildup of foulants such as scale or organic growth inside the slot will change its geometry and hence affect the calibration of the conductivity sensor 10. It is important that the slot 14 retain a stable or substantially constant volume of water (or analyte) during and after calibration for accurate measurements. Accordingly, the slot 14 should be small enough that surrounding conditions such as turbulence do not disturb the volume of water that is resident in the slot during the conductivity measurement. Otherwise it may be difficult to obtain reproducible measurements. In one embodiment, the slot is about 0.58 cm wide (0.23 in) and about 1.27 cm long (0.5 in) in an electrode support that is about 1.59 cm in diameter (0.625 in). In another embodiment, the slot may be about 0.25 cm (0.10 in) to about 2.5 cm (1.0 in) wide and about 0.64 cm (0.25 in) to about 3.8 cm (1.5 in) deep, and the electrode support may be about 0.51 cm (0.20 in) to about 5.08 cm (2.00 in) in diameter.

In one embodiment, the first and second electrodes 18, 19 and the third and fourth electrodes 28, 29 define separate sets of electrodes that each include one drive electrode and one sense electrode. A drive electrode imparts an AC current across the conductivity cell and a sense electrode detects the voltage across the cell. As shown in FIGS. 1 and 8, each set of electrodes 18, 19 or 28, 29 may include a doughnut-shaped electrode and a rod electrode. The rod electrodes 19, 29 are disposed within the doughnut-shaped electrodes 18, 28, respectively, and are concentric with the doughnut-shaped electrode. When the doughnut-shaped electrode is selected to be the drive electrode, then the rod electrode is the sense electrode. Alternately, when the doughnut-shaped electrode is selected to be the sense electrode, then the rod electrode is the drive electrode. Additionally, buildup of foulants on the electrodes 18, 19, 28, 29 themselves can diminish their ability to conduct electricity, which directly affects the calibration. It is an advantage to have a system to keep the electrodes free of foulants.

In one embodiment, the conductivity sensor 10, as shown in FIG. 2, includes a conductivity controller 32 coupled thereto. In one embodiment, the conductivity controller 32 may be coupled to the electrodes 18, 19, 28, 29. The conductivity controller 32 may control the current or voltage that is applied to the electrodes. The conductivity controller 32 may be programmable so that the conductivity sensor 10 may take conductivity readings or measurements at selected time intervals. The time intervals may be consistent or varied. The conductivity controller 32 may receive AC current, resistance, or voltage measurements from the electrodes and determine a conductivity value. The controller may be a component in a sonde to which the conductivity probe is connected. In another embodiment, the conductivity sensor 10 via controller 32 may further be coupled to a display device 34 to display the conductivity value and/or to a recorder 36 to record the conductivity value. In another embodiment, the conductivity controller 32 may be coupled to the conductivity sensor 10, the display device 34, and/or the recorder device 36 using a wireless connection. In another embodiment, the conductivity probe may include the components of the conductivity cell and operate as described in applicant's U.S. Pat. No. 6,232,786.

FIG. 1 also shows a wiping assembly 20 having a wiper element 22 coupled to a rotatable shaft 24 by a motor-driven arm 25. The wiper element 22 may be a brush or a sponge or elastomeric pad that is capable of removing biological contaminants as the element 22 passes through the slot 14. The wiper element 22 may be any material that can pass through slot 14 to remove debris without damaging the electrodes 18, 19, 28, 29. In another embodiment, the wiper may be a foamed rubber or elastomeric pad. The brush may be made of bristles that are long enough to sweep through slot 14 and across electrodes to prevent the build up of debris and growth of fouling substances, for example slimes, grasses, and/or barnacles. In one embodiment, the brush bristles are formed of a fine material which remains flexible after it has been wetted and dried. The bristles may be imitation squirrel hair available from Felton Brush Company, Londonderry, N.H. Those skilled in the art will recognize that other bristles such as goat hair might also be useful. In another embodiment, the bristles of the brush may include a stiffener 23, as described in U.S. published patent application 2005/0236014. The stiffener 23 may be made by various techniques, including for example melting the bristles together, adhering the bristles together with an adhesive, sewing the bristles together, or clamping the bristles together. The height and placement of the stiffener 23 may be varied to adjust the amount of force the bristles apply to the sensor area.

In another embodiment, as shown in FIGS. 1 and 2, the conductivity sensor 10 and the wiping assembly 20 together comprise a wipeable conductivity sensor assembly. The wiping assembly 20 is positioned adjacent the conductivity sensor 10 and positioned so that wiper element 22 can move through slot 14 of the conductivity sensor 10 to remove debris from the slot and/or the electrodes. The wiper element 22 is carried on arm 25, which is journaled to the shaft 24. The shaft is rotated to move the wiper element 22 through the slot 14. Alternatively, the wiper element 22 can be carried on a linear actuator that linearly reciprocates the wiper element 22 within the slot 14.

In one embodiment, the wiping mechanism 20 may be coupled to a wiping controller 38 to control the timing of the passing or movement of the wiper element 22 through slot 14. The wiping controller 38 may be programmable. In one embodiment, the wiping controller 38 controls the movement of the wiper element 22 so that the wiper element 22 passes through slot 14 at a selected repeating time interval. The time interval may be consistent or may be varied. In another embodiment, the wiping controller 38 controls the movement of the wiper element 22 so that the wiper element 22 passes through slot 14 prior to the conductivity sensor 10 measuring the conductivity of the fluid within slot 14. The wiping controller may be a component of a probe that includes the wiping mechanism 20 or of a sonde that is connected to the wiping mechanism 20.

In one embodiment, the wipeable conductivity sensor assembly may include a stand or holder for holding the conductivity sensor 10 and the wiping mechanism 20 in place within the fluid, whether the fluid is still or moving. In another embodiment, the conductivity sensor may be mounted within a multi-probe assembly or sonde as illustrated in U.S. Pat. No. 6,779,383 and wiped with a wiper element that cleans not only the conductivity sensor but other sensors in the probe. Thus, one embodiment of the invention is the sensor itself having the open electrode design and another embodiment is the combination of the sensor and the wiper element. A further embodiment is the sonde described in U.S. Pat. No. 6,779,383 modified to include the conductivity sensor disclosed herein.

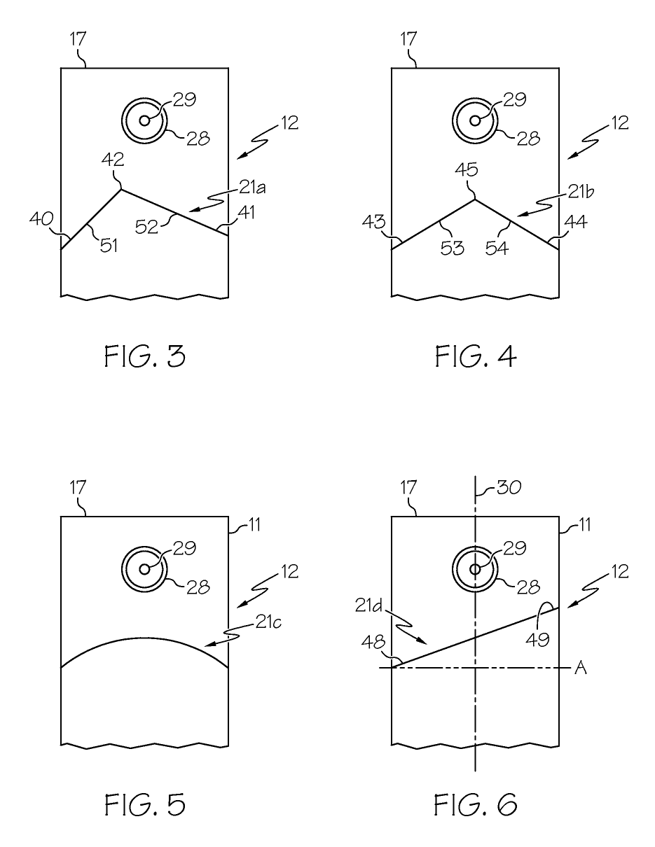

FIGS. 3-6 illustrate different profiles for the floor 21 of slot 14. These floor profiles are advantageous because they direct bubbles from the slot that otherwise would interfere with taking accurate readings. Bubbles can form in the slot 14 as the probe or sensor is placed into the fluid to be measured, or as a result of turbulence in the fluid such as natural movement of water, for example, in lakes, streams, ponds, oceans, etc., movement of plant and animal life, and/or movement of the wiper element through the slot. Any bubbles that do form flow out of the slot because the contours direct the bubbles away from the plurality of electrodes. The portion of the upper electrode support 12 shown includes the second electrode support arms 17, the electrodes 28, 29 and floor 21 of the slot. Electrodes 28, 29 are a set of concentric electrodes configured as a doughnut-shaped electrode 28 and a rod electrode 29.

Floor 21a, shown in FIG. 3, includes a first end 40, a second end 41, an apex 42, and a first surface 51 and a second surface 52. Floor 21a has a first surface 51 that gradually slopes upward from the first end 40 to the apex 42 and a second surface 52 that gradually slopes upward from the second end 41 to the apex 42. In this embodiment, the apex 42 is positioned to the side of the dot-shaped electrode 29 rather than centered thereunder. The first surface 51 and the second surface 52 may have the same or different grades defining their respective slopes.

Floor 21b, shown in FIG. 4, includes a first end 43, a second end 44, an apex 45, and a first surface 53 and a second surface 54. Floor 21b has a first surface 53 that gradually slopes upward from the first end 43 to the apex 45 and a second surface 54 that gradually slopes upward from the second end 44 to the apex 45. In this embodiment, the apex 45 is centered under electrode 18. The first surface 53 and the second surface 54 may have the same or different grades defining their respective slopes.

FIG. 5 illustrates a floor 21c that is crowned. The curvature of the floor is preferably spherical but it could assume other curved crowned geometries.

Floor 21d, shown in FIG. 6, includes a first end 48 and a second end 49 where one of the ends is a shorter longitudinal distance from the first end 11 of the conductivity sensor 10. Floor 21d gradually slopes upward from the first end 48 to the second end 49. The gradually sloping floor 21d may have an angle of about 10 to about 30 degrees relative to a horizontal line A drawn from the first end 48 and traversing the central axis 30 of the conductivity probe, and in particular an angle of about 20 to about 30. Similar angle ranges may be used for the first surfaces 51, 53 and the second surfaces 52, 54 of FIGS. 3 and 4. One of skill in the art will appreciate that the angle for the second sides 52, 54 are relative to a line drawn from each of the second ends perpendicular to the central axis 30.

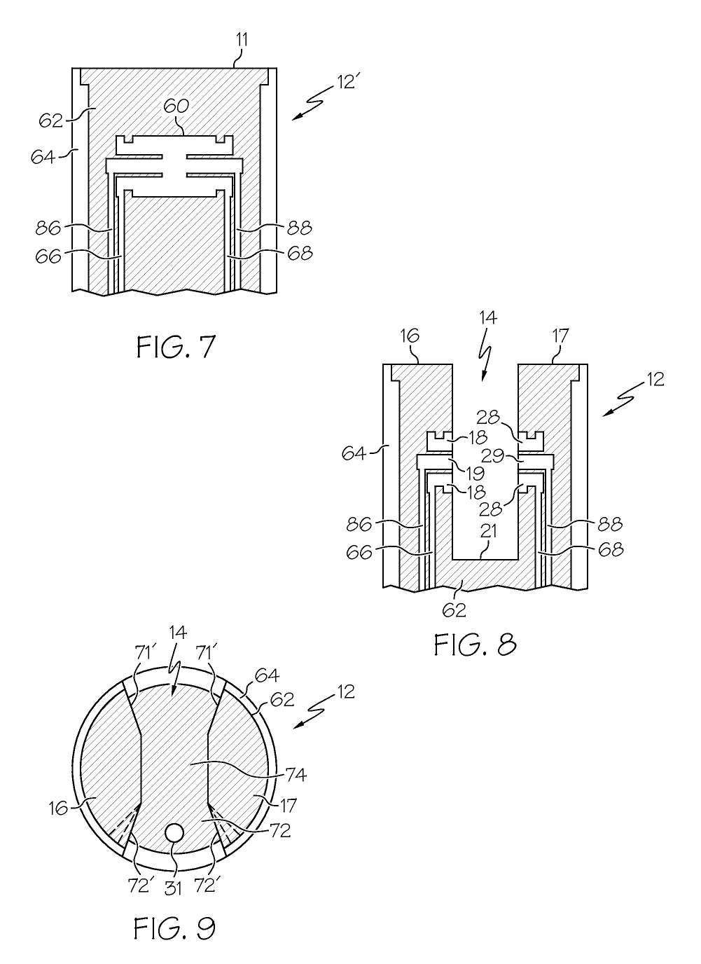

In one embodiment, the electrode support 12 is manufactured initially with a preform electrode element 60 (FIGS. 7, 10-13) and then a portion of the support and electrode element is removed to form the four separate electrodes 18, 19, 28, 29 and the slot 14 (FIG. 8). As seen in FIG. 7, the preform electrode element 60 having a first, second, third, and fourth electrode leads 66, 68, 86, 88 connected thereto, with the first and third leads connected to one end of the preform electrode element and the second an fourth leads connected to the second end of the of the preform electrode element. The preform electrode element, including the four leads, is encased in an electrically insulating material 62, for example, a plastic or resin or ceramic, to form am encased preform electrode body 12′, preferably a plastic-encased preform electrode body 12′. The plastic-encased preform electrode body 12′ defines the first end of the conductivity sensor 10 and may include an outer housing 64 encasing or surrounding at least the length of the plastic-encased preform electrode intermediate.

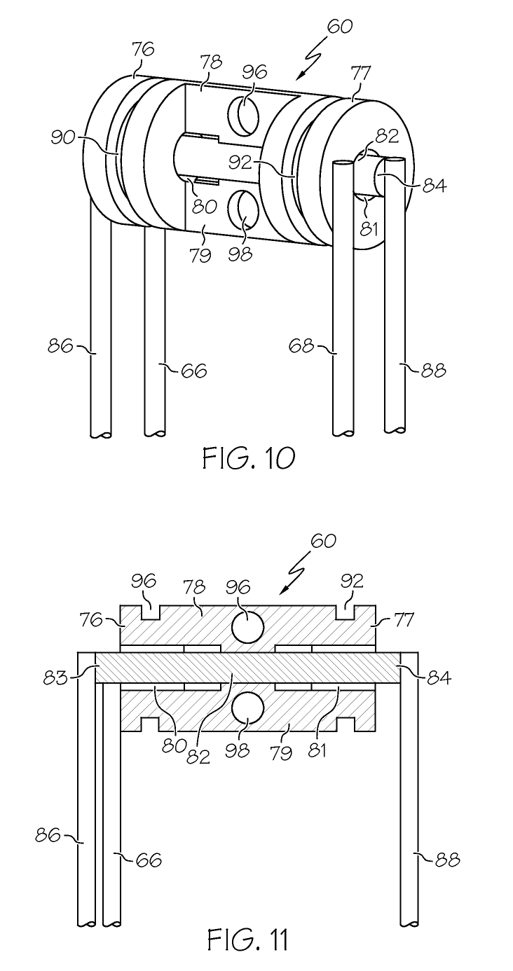

Referring now to FIGS. 10-11, one embodiment of a preform electrode element 60 is shown to include a first electrode end 76 and a second electrode end 77 opposite the first electrode end. The first electrode end 76 includes a central bore 80 and the second electrode end 77 includes a central bore 81. In one embodiment, the central bores 80, 81 may be uniform cylindrical bores and the electrode end 76, 77 may have a generally cylindrical exterior. The preform electrode element 60 includes a rod 82 extending from the one end to the other end of the preform electrode through the central bores 80, 81 of the first and second electrode ends 76, 77. The first and second electrode ends 76, 77 are integrally connected together by interposing first and second arms 78, 79 that are separated from one another by rod 82, which extends along their length. The rod 82 is integrally connected to at least a portion of the length of both the first and the second arms 78, 79 to hold the rod centrally within the bores of the first and the second electrode ends 76, 77. The centrally positioned rod 82 does not contact the first and second electrode ends 76, 77 as it passes through bores 80, 81.

The first electrode end 76 is connected to a first lead 66 and the second electrode end 77 is connected to a second lead 68. The first end 83 of rod 82 is connected to a third lead 86 and the second end 84 of rod 82 is connected to a fourth lead 88. The four leads, 66, 68, 86, 88 are coupled to the conductivity drive circuitry depicted as the ‘conductivity controller’ 32 in FIG. 2.

The first and second electrode ends 76, 77 may each include a recess 90, 92 in their outer generally cylindrical surfaces. The recesses 90, 92 are areas where molded material can embed itself for a stronger more resilient connection to the electrodes 76, 77. In one embodiment, the recesses 90, 92 may be continuous or discontinuous annular recesses. During molding, the molding material also embeds itself between the rod 82 and the concentric generally cylindrical electrode ends 76, 77 as seen in FIG. 7. As a result, the rod and electrode ends are electrically insulated from one another by the molding material.

The arms 79, 80 may each include an alignment feature for aligning the preform electrode element 60 in a mold. The alignment feature may be holes 96, 98, or pins, notches, or the like that hold the preform electrode element 60 in place while another material is molded over and/or around it, for example by injection molding.

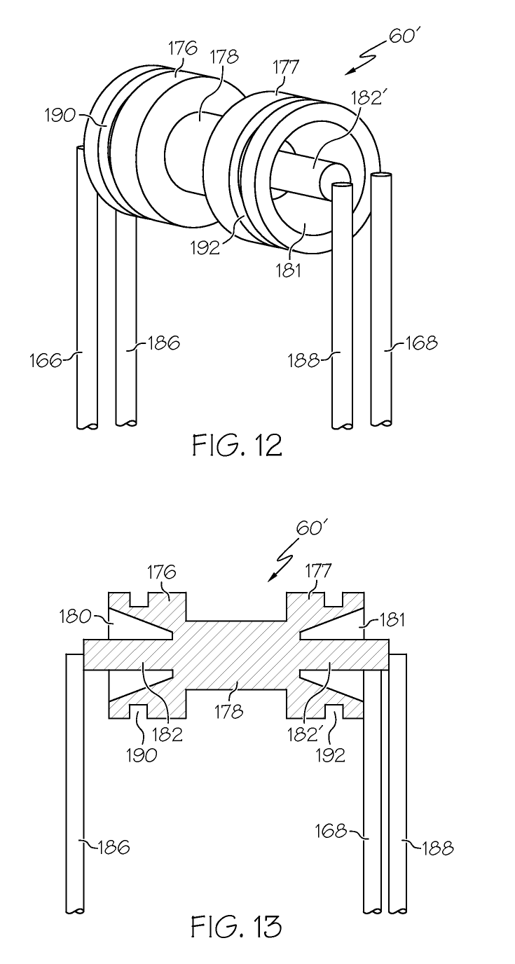

Referring now to FIGS. 12-13, another embodiment of a preform electrode element, generally designated 60′, is shown to include a first electrode end 176 and a second electrode end 177 opposite the first electrode end. The first electrode end 176 includes a tapered bore 180 and the second electrode end 177 includes a tapered bore 181. In one embodiment, the central bores 180, 181 may be conical bores. The bores 180, 181 each have a larger opening at the outermost end of their respective electrode ends 176, 177 and a narrower terminus toward the center of the preform electrode element 60′. Within the center of each the tapered bores 180, 181 is a rod of electrode material 182, 182′. The tapered bores may be machined into the electrode ends 176, 177 and the machining process forms the rod electrode material as the bore is formed. The centrally positioned rods 182, 182′ do not contact their respective first or second cylindrical electrode ends 176, 177. Alternately, the preform electrode element may be cast/molded into the desired form.

The preform electrode element 60′ is generally dumb-bell shaped with an arm 178, rod, bar, or the like integrally connecting the first and second cylindrical electrode ends 176, 177. The first cylindrical electrode end 176 is connected to a first lead 166 and the second cylindrical electrode end 177 is connected to a second lead 168. Rod 182 is connected to a third lead 186 and rod 182′ is connected to a fourth lead 188. The four leads, 166, 168, 186, 188 are coupled similarly to that described above for preform electrode element 60.

The first and second cylindrical electrode ends 176, 177 may each include a recess 190, 192 in their outer cylindrical surfaces for a stronger more resilient connection of molded material to the cylindrical electrodes. The preform electrode element 60′ may include an alignment feature such as a hole, pin, notch, or the like to hold the preform electrode element 60′ in place while another material is molded over or to it, for example by injection molding. The injected material will also embed itself between the rods 182, 182′ and the cylindrical electrode ends 176, 177. The material between the rods and the cylindrical electrode ends electrically insulates these electrodes from one another.

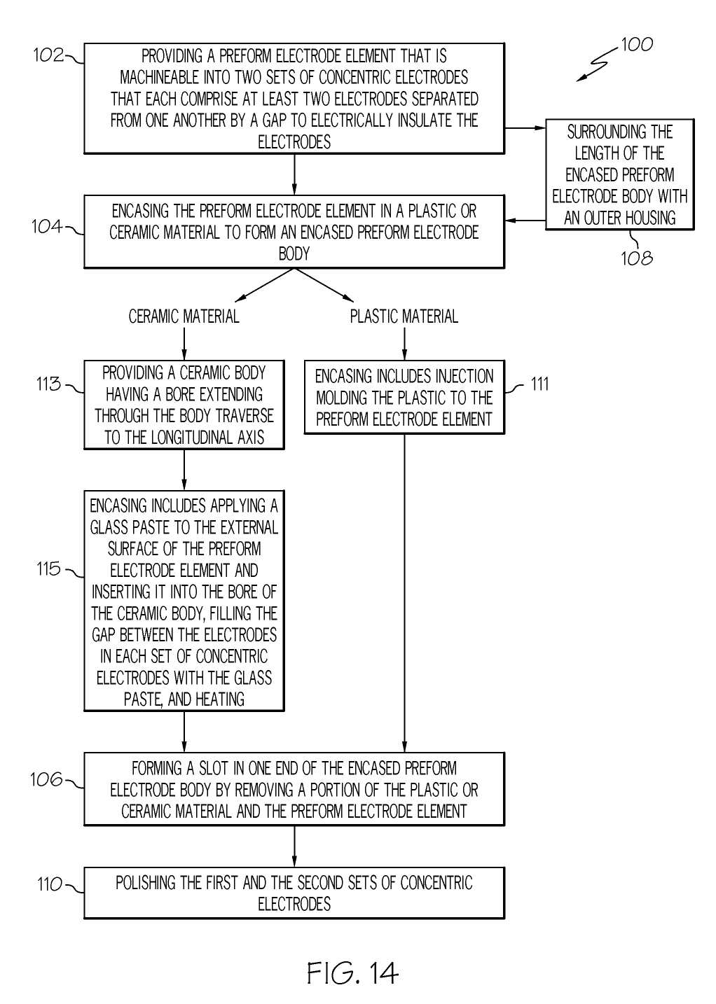

Referring to FIG. 14, one embodiment of a process, generally designated 100, for manufacturing the forked electrode support is depicted. The process 100 includes the step 102 of providing a preform electrode element, the step 104 of encasing the preform electrode element in an electrically insulating material to form an encased preform electrode body, and the step 106 of forming a slot in the encased preform electrode body by removing a portion of the electrically insulating material and a portion of the preform electrode element. The preform electrode element is machineable into two sets of concentric electrodes that each comprise at least two electrodes separated from one another by a gap to at least electrically insulate the electrodes. The slot divides the end of the encased preform electrode body into a first arm and a second arm. The first arm includes a first set of concentric electrodes and the second arm includes a second set of concentric electrodes that are aligned with one another as described above.

Still referring to FIG. 14, in another embodiment, the process may include the step 108 of surrounding the length of the electrode support with an outer housing 64 before the removing step. In one embodiment, the outer housing 64 can be added after the encasing step. In another embodiment, the process may include the step 110 of polishing the first and second sets of concentric electrodes.

The electrically insulating material may be a plastic, ceramic, or a resin. In an embodiment where the plastic material is being used to encase the preform electrode element, the step of encasing 104 may include the step 111 of injection molding the plastic over the preform electrode element.

In an embodiment where the ceramic material is being used to encase the preformed electrode element, the process may include the step 113 of providing a ceramic body having a bore extending through the body traverse to the longitudinal axis thereof and the step of encasing 104 may include the step 115 of applying a sealing glass to the external surface of the preform electrode element and assembling it into the bore of the ceramic body and heating the assembly to bond it together. The step 115 may also include filling the gap between the electrodes in each set of concentric electrodes with the sealing glass before heating.

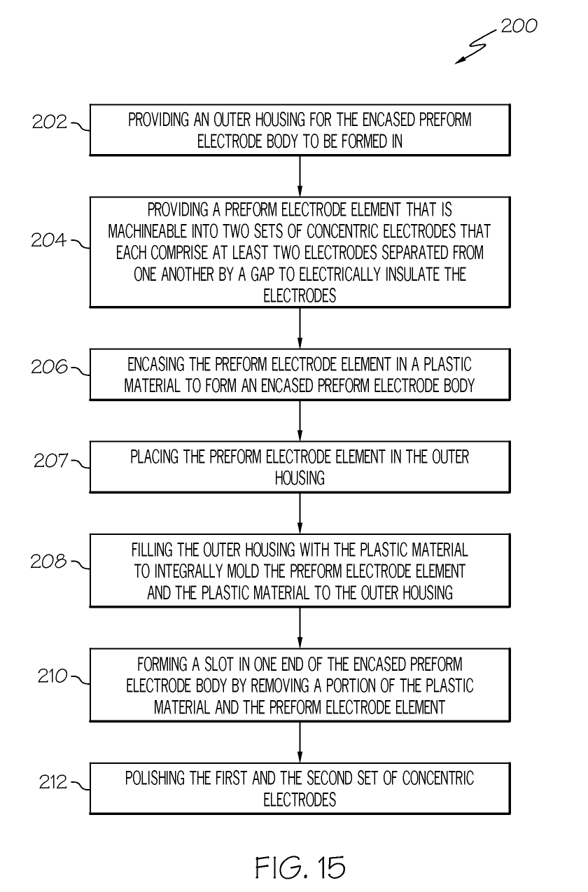

Now referring to FIG. 15, another embodiment of a process, generally designated 200, for manufacturing the forked electrode support is depicted. The process includes the step of providing 202 an outer housing, like the outer housing 64 in FIG. 7, that may be a die for forming the encased preform electrode body and the step of providing 204 a preform electrode element that is machineable into two sets of concentric electrodes that each comprise at least two electrodes separated from one another by a gap to at least electrically insulate the electrodes. The process also includes the step 206 of encasing the preform electrode element in a plastic material to form an encased preform electrode body. In this embodiment, since the outer housing is provided, the step of encasing includes placing 207 the preform electrode element in the outer housing and filling 208 the outer housing with the plastic material to integrally mold the preform electrode element and the plastic material together and to the outer housing. The process then includes the step 210 of forming a slot in one end of the encased preform electrode body by removing a portion of the plastic material and a portion of the preform electrode element. The slot divides the end of the encased preform electrode body into a first arm and a second arm. The first arm includes a first set of concentric electrodes and the second arm includes a second set of concentric electrodes, with the first and second sets aligned opposite one another as described above. In another embodiment, the process may include the step 212 of polishing the first and second sets of concentric electrodes.

This process provides a watertight electrode support 12 with a plurality of electrodes that are electrically insulated from each other by the material filling the gap between the two electrodes in each arm of the electrode support. This process is superior to prior art methods because it results in more closely aligned electrodes that oppose one another across the slot. The assembled electrode support 12 as well as the entire conductivity sensor 10 is a sealed body for underwater use. The assembly may be watertight even up to about 6000 meters and/or 10,000 psi.

The preform electrode element may be a non-corrosive material since it will be exposed to water or other fluids for extended periods of time while taking measurements. For example, the preform electrode element, may be or include at least one of titanium, nickle, preferably nickle 200, or a nickel-chromium alloy, such as an INCONEL® commercially available from Special Metals Corporation, preferably INCONEL® 600. INCONEL® 600 is a nonmagnetic, nickel-based high temperature alloy possessing an excellent combination of high strength, hot and cold workability, and resistance to ordinary forms of corrosion. Any other material with similar properties to INCONEL® 600 may be used. The preform electrode element may also be made from or include graphite or graphite-impregnated resins and plastics.

The preform electrode element may be formed into its preform design by metal-injection molding and/or by turning and/or machining it. Metal-injection molding is a process that begins by mixing a metal powder with a thermoplastic binder to produce a homogeneous feedstock, often with approximately 60 volume % metal powder and 40 volume % binders. The feedstock is placed into an injection molder and molded to form a net shape green part. After injection molding, two thermal processes occur. First, the binder is removed from the green part via an evaporative process called “debinding.” Second, after debinding, the part is sintered to form a high-density metal part. Sintering occurs at high temperatures, up to 2300° F. (1260° C.), near the melting point of the metal, under a dry H₂ atmosphere or inert gas atmosphere. During sintering, the part will shrink isotropically to form a dense shape. Since, the complex shape of the molded part is retained through the process, close tolerances in the as-sintered part can be achieved. Other variations to this process may be used. Alternately, the preform electrode element may be formed by pressed powder sintering or investment casting.

The electrically insulating material for encasing the preform electrode element may be an engineering thermoplastic material with good material strength that lends itself to having the slot formed therein. The thermoplastic may be water, corrosion, and/or chemically resistant, and electrically insulating. Applicants have found that a superior watertight bond is formed between the preform electrode element and the plastic material when the coefficient of thermal expansion (CTE) of each material is generally similar. Likewise, minimizing the material expansion difference between the preform electrode element and the plastic material is beneficial for the dimensional stability of the conductivity cell (the cell constant). The watertight bond is important since the conductivity sensor is often used under water at significant depths and experiences increased pressure as it descends. If a gap occurs between the electrodes and the plastic material water may be able to enter the conductivity sensor and damage its electrical components.

The thermoplastic material may an acetal, acrylic, acrylonitrile-butadiene-styrene terpolymer, a polyamide, a polycarbonate, a polyetherimide, a polyphenylene ether, a polyphenylene sulfide, a polysulfone, or a thermoplastic poyester. In one embodiment the thermoplastic material is an imide, and is preferably a glass-filled imide. The imide may be a 30% glass-filled polyamide-imide resin such as TORLON® 5030 available from Solvay Advanced Polymers, L.L.C. or a 40% glass-filled polyetherimide such as ULTEM® 2400 available from SABIC Innovative Plastics.

The plastic member encases the preform electrode element as shown in FIG. 8 and may be molded together, preferably by injection molding, in particular by insert molding. However, the molded assembly is not limited to being made by injection molding. One of skill in the art will appreciate that the injection molding technique may be a known or after-developed technique. Examples of molding techniques are described in “Injection Molding Alternatives: A Guide for Designers and product Engineers,” by Jack Avery published by Hanser/Gardner Publication, 1998 (the “Avery handbook”). Alternately, a thermoset material may be used, for example an epoxy cure, as described in the Avery handbook.

In an alternate embodiment, the electrically insulating member includes a resin. The resin may be a polyester resin, an epoxy resin, and combinations thereof, but is not limited thereto. Other electrically insulating resins are known in the art and may be equally applicable.

The outer housing may define the outer surface of the conductivity sensor 10 or at least the outer surface of the electrode support 12. In one embodiment, the outer housing surrounds the length of the electrode support and/or the conductivity sensor without covering the first end and/or the second end of the conductivity sensor. The outer housing 64 may be a sheet that is wrapped around the plastic member 62 encasing the preform electrode element and sealed to form the casing or a housing that is fitted over the plastic member. The outer housing may be bonded to the plastic member, for example with an adhesive. The adhesive may be any adhesive that can form a strong bond that is watertight, for example an epoxy. Alternately, the housing may be the die that the plastic member and preform electrode element are molded together in such that the housing is integral with the plastic member encasing the preform electrode element. The housing may be a hollow cylindrical sleeve or any other shape and/or design to match the design of the electrode support.

The outer housing may be a metal and/or an anti-biofouling material. The metal may be water resistant and corrosion resistant. For example the casing may be titanium, stainless steel, nickel, copper, and alloys thereof. In one embodiment, the casing is titanium. In another embodiment, the casing is an antifouling copper-nickle alloy with a high copper content. For example, the antifouling copper-nickle alloy may be a 90-10 CuNi alloy or a 70-30 CuNi alloy.

The portion of the preform electrode element and plastic member removed to form slot 14, see FIG. 8, may be removed by milling, grinding, turning, machining, etching, or other known methods. Upon removal the concentric electrodes are revealed and are in alignment with one another (FIG. 8), in particular the outer concentric electrodes 18, 28 are aligned with one another and the rod central electrodes 19, 29 are likewise aligned with one another across the slot. The amount of material removed to form slot 14 may be selected to define a known volume for determining the conductivity cell constant for the slot and ultimately the conductivity of a fluid that fills the slot. The material can be removed to a pre-selected width and depth and thereby defining the volume of the slot.

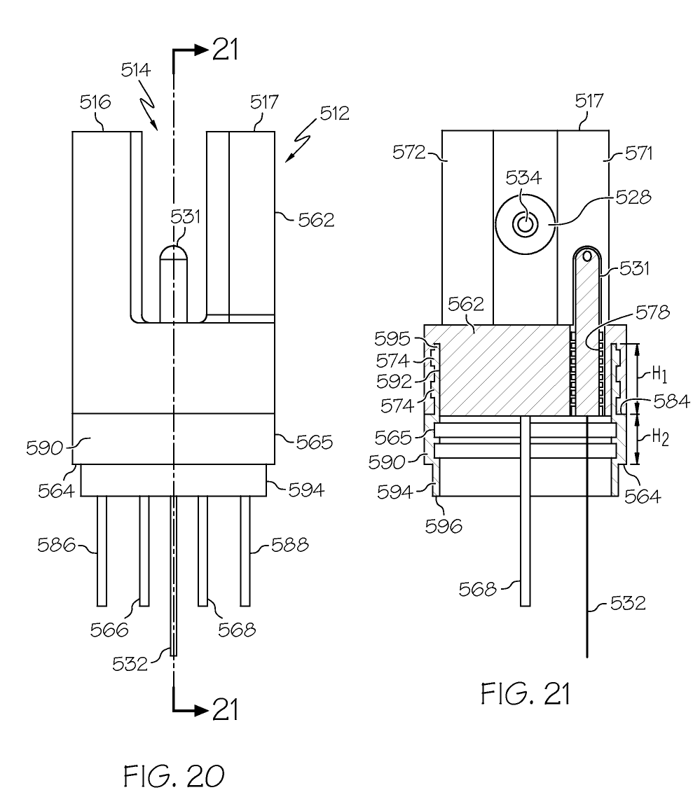

Furthermore, as shown in FIG. 9 the slot 14 may include a temperature probe 31. The slot may be uniform through the center of the electrode support or, in another embodiment, the slot 14 may include an entrance 71, a central passage 74, and an exit 72 where the entrance and exit each have at least a portion thereof that is wider than the central passageway. The entrance 71 may be a tailored entrance that advantageously accepts and directs a wiper and/or a brush into and through the slot 14, especially the central passageway 74, to keep the slot clear of contaminants. The exit 72 may likewise be tailored but in the opposite direction compared to the entrance 71 to advantageously direct the wiper and/or brush from the slot 14. The entrance 71 and the exit 72 may both be funnel-shaped openings that funnel inward toward the concentric electrodes (not seen in this view), i.e., the electrode supports gradually slope radially inward toward the central axis from the periphery of the electrode support to the beginning of a central passage 74. The funnel shaped opening of the entrance 71 is defined by walls 71′ and may be at different angles making the outermost portion of the entrance 71 wider. Likewise, the funnel shape opening of the exit 72 is defined by walls 72′, which may be at different angles making the outermost portion of the exit wider. Alternate angles, positions of walls 71′ and 72′ are shown in FIG. 9 as dashed lines. In one embodiment, only the walls 71′ and 72′ on one electrode support arm are tailored to facilitate the entrance and exit of the wiper (see FIGS. 20-21, only the second electrode arm 517 has angled walls 571 and 572).

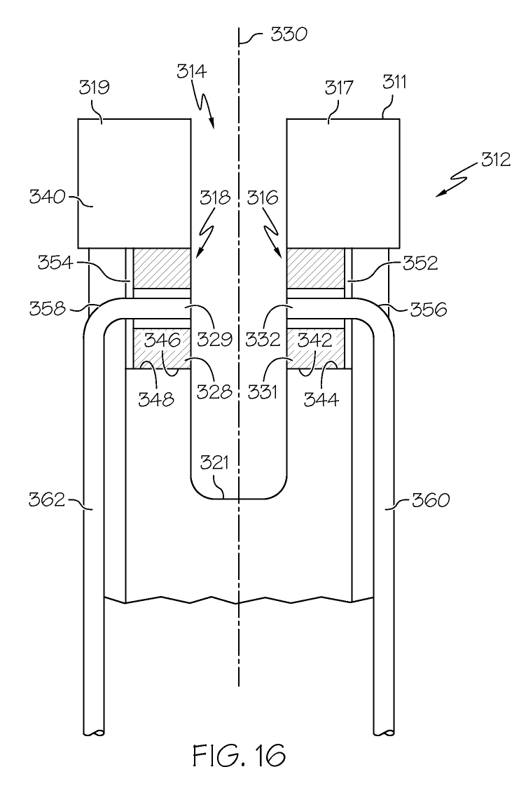

Referring now to FIG. 16, an electrode support 312 is shown that is manufactured from a ceramic body 340 and a first electrode pair 316 comprising electrode 331 and electrode 332 and a second electrode pair 318 comprising electrode 328 and electrode 329 sealed together using well-known glass sealing methods. The electrode support 312 has a central longitudinal axis 330 and defines the first end 311 of a conductivity sensor/probe. The electrode support 312 includes a slot 314 defined by a first electrode support arms 317, a second electrode support arms 319, and a floor 321. The first electrode support arms 317 includes the first electrode pair 316 and the second electrode support arms 319 includes the second electrode pair 318. The first electrode support arms 317 and the second electrode support arms 319 are positioned opposite one another such that the first electrode pair 316 is opposite the second electrode pair 318. As discussed above, the electrodes may be titanium. The first and second receptacles 352, 354 may each include a bore 356, 358 extending from the interior of each receptacle to the outer surface of the ceramic body so that electrode lead wires 360, 362 (more lead wires can be included) can be connected to the first and second electrodes of each set of electrodes.

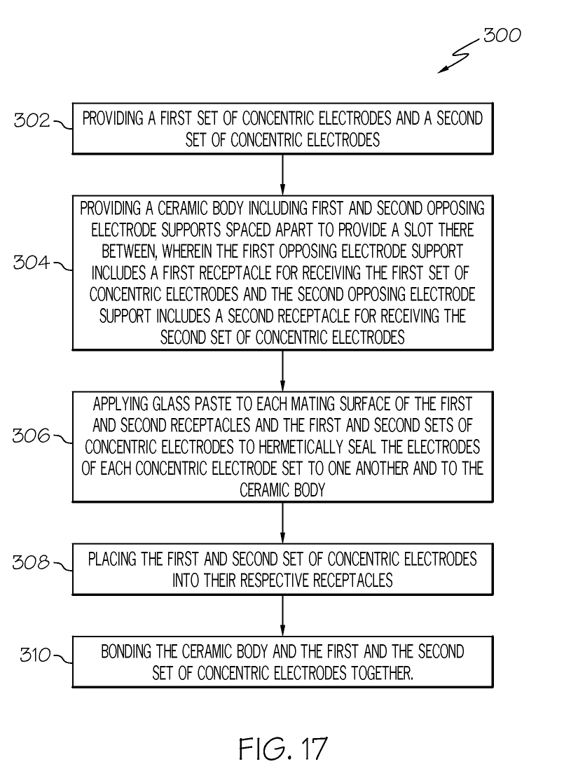

The process of manufacturing the ceramic electrode support 312 of FIG. 16 is generally designated 300 in FIG. 17. The process 300 includes step 302 providing a first and a second set of concentric electrodes 316, 318, step 304 providing a ceramic body 340 including first and second opposing electrode supports 317, 319 spaced apart to provide a slot 314 therebetween, the first opposing electrode support 317 including a first receptacle 352 for receiving the first set of concentric electrodes 316 and the second opposing electrode support 319 including a second receptacle 354 for receiving the second set of concentric electrodes 318, step 306 applying sealing glass to the mating surfaces of the first and second receptacles and the first and outer electrodes 328, 331 of each electrode set 342, 344, 346, 348 and applying sealing glass between the outer electrodes 328, 331, and the inner electrodes 332, 329 of each electrode set, step 308 placing the first and the second set of concentric electrodes 316, 318 into their respective receptacles 352, 354, and the step 310 of bonding the ceramic body and the first and the second set of concentric electrodes together. The bonding may include heating the electrode support 12 to melt the sealing glass. The process may also include the step of grinding and/or polishing, the ceramic, metal, and glass interface of the electrodes.

The ceramic body 240 may be a machineable ceramic, in particular a machineable ceramic that includes aluminum oxide. In one embodiment, the ceramic body may be a machineable glass-ceramic. Suitable machineable ceramic is available under the trade mark MACOR®. The ceramic body may be available as rod stock that is cut and machined to include the slot and the first and second receptacle for the sets of electrodes or a bore that receives a preform electrode element.

The sealing glass may be any commercially available or after developed metal-ceramic paste that can fuse the plurality of electrodes to the ceramic body. Preferably the sealing glass forms a water tight and electrically insulating seal between the electrodes and the ceramic body. The sealing glass may a powder, paste, granulate, or preform. When the sealing glass is a powder it is mixed with an appropriate solvent to form a paste that can be painted, spread, or sprayed onto the parts. Sealing glass is commercially available from Schott Electronic Packaging.

The appropriate sealing glass depends on the materials being joined, the required temperature profile, and the coefficient of thermal expansion. The coefficient of thermal expansion as discussed above is an important factor. For matched seals, the coefficient of thermal expansion of the glass is matched as closely as possible to those of the sealing partners. When the electrodes are titanium and the ceramic is MACOR®, then the sealing glass should be suitable for fusing titanium to MACOR®.

The parts after being coated with the sealing glass are assembled and heated to the temperature for fusing the parts together. Sealing glass typically has a processing temperature of 800-1000° C. When the sealing glass is fusing titanium and MACOR®, the assembled electrode support is heated to about 1000° C.

In an alternate embodiment, the first electrode pair 316 and the second electrode pair 318 may be formed from a preform electrode element, such as either of the preform electrode elements 60, 60′ of FIGS. 10 and 12, that is receivable in the receptacles of the first and second electrode support arms 352, 354. In this embodiment, at least one of bores 356, 358 needs to be large enough to allow the preform electrode element to slide into the ceramic body. As shown in FIG. 16, the ceramic body already included slot 314, so only the preform electrode element is machined, milled, ground, etched, or the like to remove the portion of the preform electrode element that is in the slot.

As explained above, sealing glass may be used to seal the preform electrode element to the ceramic body.

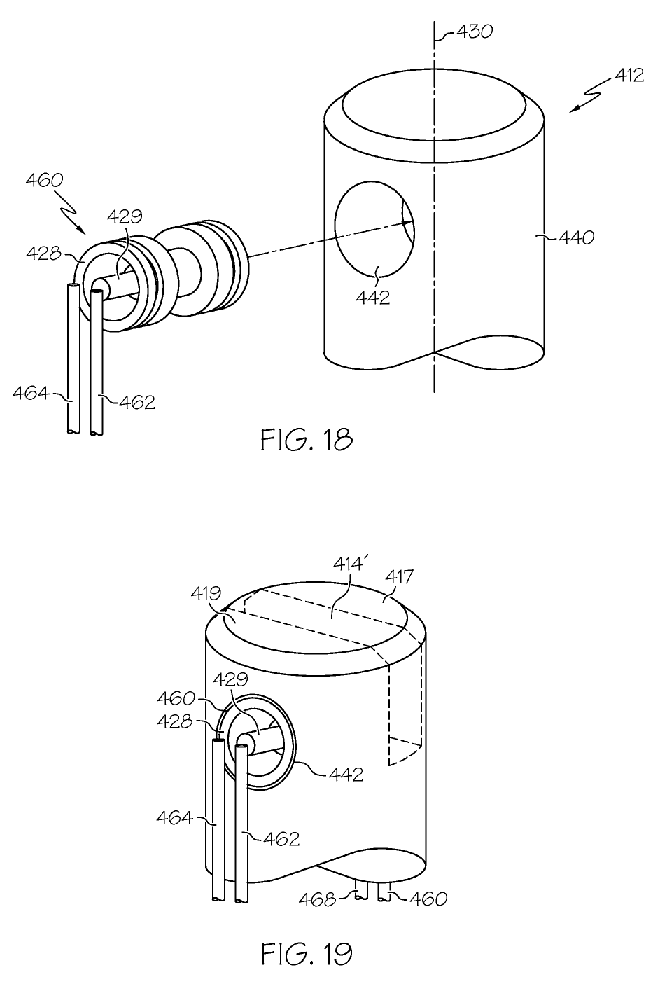

Now referring to FIGS. 18-19, in another embodiment, the electrode support 412 is manufactured from a ceramic body 440 that includes a bore 442 extending through the ceramic body traverse to the longitudinal axis 430, but no slot. The bore 442 may be perpendicular to the longitudinal axis for alignment of the first and second electrode pairs to be formed in the first and second electrode support arms 417, 419 that will define a slot 414 once a slot is machined, milled, ground, etched, or formed by other known methods be removing a portion of the ceramic body and a portion of the preform electrode element that is within the portion of the ceramic body to be removed. A preform electrode element 460 such as a preform electrode element like 60 or 60′ of FIGS. 10 and 12 is received in the bore 442 of the ceramic body. The preform electrode 460 may include a first lead 462 connected to the portion of the preform electrode element that will become the inner electrode 429 and a second lead 464 connected to the portion of the preform electrode element that will become the outer electrode 428 of the second set of electrodes in the second electrode support arms 419. The other end of the preform electrode element 460 may not have lead wires attached so that the preform electrode element 460 is insertable into the bore 442 of the electrode support 412.

For the embodiments having a ceramic body, the difference between the ceramic body's coefficient of thermal expansion and that for the preformed electrode may be about 10% or less, preferably about 5% or less, or more preferably about 1% or less. This provides a superior watertight bond between the ceramic and the preformed electrode and helps prevent the ceramic from cracking.

At any time after insertion of the preform electrode element 460 additional lead wires, like lead wires 460, 468 shown in FIG. 19, may be attached to the other end by soldering or welding. Again, sealing glass may be used, as explained above, to seal the electrodes to the ceramic body. Thereafter, a portion of the ceramic body 414′ shown in FIG. 19 and the preform electrode therein may be removed as described above to form a slot and a first electrode support arms 417 and a second electrode support arms 419.

For any of the above conductivity electrodes that includes a preform electrode element with a conically-shaped gap between the electrodes, like that shown in FIGS. 12-13, the conical shape provides a means to control the gap between the electrodes. When the slot is formed in the electrode support, the slot can be formed at a minimum width that will just reveal the two sets of concentric electrodes. Thereafter the slot may be widened gradually as needed until a desired gap between the two electrodes in each set of electrodes is reached. The slot may even be widened by only removing material from one of the arms that defines the slot. This can correct misalignments between the diametrically opposed sets of concentric electrodes. Such adjustment should be done during manufacturing and prior to calibration of the conductivity cell because the distance between the electrodes and the area of the cell effect the cell constant.

Now referring to FIGS. 20-21, an electrode support, generally designated 512, is manufactured, as described above, with a preform electrode element encased in an electrically insulating material such as a plastic material 562 or a resin and thereafter a portion of the electrode and plastic are removed to form the forked support 512 having a first electrode arm 516 and a second electrode arm 517 defining a slot 514 therebetween. The plastic is preferably injection molded. As seen in FIG. 21, the second electrode arm 517 includes an outer concentric electrode 528 and a rod central electrode 529. The outer concentric electrode 528 is connected to a first electrode lead 588 and the rod central electrode 529 is connected to a second electrode lead 568. Aligned with the outer concentric electrode 528 and the rod central electrode 529 but positioned across the slot 514 within the first electrode arm 516 is another outer concentric electrode connected to a third lead 586 and another rod central electrode connected to a fourth lead 566. These four leads 566, 568, 586, and 588 can be connected to a circuit such as the main circuit board housed with a probe body.

The electrode support 512 may include a temperature sensor 531 positioned in slot 514. The temperature sensor 531 is mounted in a bore 570 in the plastic material 562. The temperature sensor 531 may include protrusions 578 on is exterior surface of the end received in the bore 570 to connect the sensor to the bore or to enhance bonding between the sensor and the plastic. The protrusions 578 may be threading, annular protruding rings, or any other pattern of protrusions suitable to connect or enhance bonding of the sensor to the plastic material. Preferably, a watertight seal is present between the temperature sensor 531 and the bore 570.

The bore 570 may be formed when the plastic 562 is injection molded or may be formed after molding using known machining, etching, boring, etc. techniques. Extending from the end of the temperature sensor 531 received in bore 570 is an electrical lead 532. The electrical lead 532 can be connected to a circuit such as the main circuit board housed with a probe body.

The plastic material 562 may be a suitable plastic, such as those described above. The plastic material 562 is preferably over-molded onto a connecting ring 565. The connecting ring 565 has a central annular sleeve 590, an integral upper annular sleeve 592 defining the first end 595 of the connecting ring and an integral lower annular sleeve 594 defining the second end 596 of the connecting ring. Both the upper annular sleeve 592 and the lower annular sleeve 594 have a smaller outer diameter compared to the central annular sleeve 590. Accordingly, a first annular step 584 is formed where the upper annular sleeve 592 meets the central annular sleeve 590 and a second annular step 564 is formed where the lower annular sleeve 594 meets the central annular sleeve 590. The first annular step 584 can be a seat or stop for the over-molded plastic 562 and the second annular stop 564 can be a seat or stop that mates against an end of a probe body, like those described in commonly assigned U.S. patent application Ser. No. 12/773,995, PROBE AND PROCESS OF ASSEMBLING SAID PROBE, (the “ASSEMBLING application”) filed May 5, 2010 and incorporated herein by reference in its entirety. The connecting ring 565 may be a welding ring that can be laser welded to a probe body as disclosed in ASSEMBLING application.

The upper annular sleeve 592 may include one or more protrusions 574, for example continuous or discontinuous annular rings or any other pattern of protrusions suitable to enhance adhesion of the plastic material to the upper annular sleeve of the connecting ring. In an alternate embodiment, the upper annular sleeve 592 may be scored or have recessed groves to enhance adhesion. The height H₁ of the upper annular sleeve 592 is preferably greater than the height H₂ of the central annular sleeve 590. This provides for a larger surface area for over-molding the plastic and enables the connecting ring to support the plastic material and the electrodes.

The connecting ring 565 is preferably a metal ring. The metal for the ring may be any suitable metal for underwater use and in forming a water tight seal when affixed to a probe body. Suitable metals includes those described above for the housing 64 of FIG. 7-9. In one embodiment, the connecting ring 565 is titanium.

For a titanium connecting ring, Applicants have found that improved adhesion to the over-molded plastic is achieved when the titanium is silanized prior to the over-molding step. The titanium is silanized using know techniques and commercially available silane coupling agents. The appropriate choice of silanes, solvents, and other conditions depend upon the system in question, and are described by the silane coupling agent's manufacturer's literature, such as Advanced Polymer, Inc., Mitsubishi International Corporation, Momentive Performance Materials, Power Chemical Corporation, Gelest, Inc., and texts on the subject (“Silane Coupling Agents” by Edwin Pleuddemann; Plenum Press, New York, 1982, incorporated herein by reference in their entirety).

The upper annular sleeve 592 or the entire connecting ring 565 may be silanized. Any suitable silane may be used that can act as a coupling agent between the plastic material 562 and the metal of the connecting ring 565. When the connecting ring is titanium and the plastic is a glass-filled imide resin, the silane coupling agent is preferably an amino silane, and more preferably a primary amino silane. In one embodiment, the silane is Gamma-aminopropyltrimethoxy silane.

Other silane coupling agents and methods of silanation are disclosed in U.S. Pat. No. 5,622,782, International Published Application WO 99/20705, U.S. Patent Application Publication No. 2003/0113523, and an article by J. Matinlinna, M. Ozcan, L. Lassila, and P. Vallittu on “the effect of a 3-methacryloxypropyltrimethoxysilane and vinyltriisopropoxysilane blend and tris(3-trimethoxysilylpropyl)isocyanurate on the shear bond strength of composite resin to titanium metal” (Dental Materials, Vol. 20, Issue 9, pgs. 804-813), all of which are incorporated herein by reference in their entirety.

Silanes can be applied with various methods such as solution treatment or bulk deposition for particulates, or chemical vapor deposition when a monolayer deposition is desirable. Deposition from aqueous alcohol solutions is the most facile method for preparing silylated surfaces. A 95% ethanol-5% water solution is adjusted to pH 4.5-5.5 with acetic acid. Silane is added with stirring to yield a 2% final concentration. Five minutes should be allowed for hydrolysis and silanol formation. Large objects are dipped into the solution, agitated gently, and removed after 1-2 minutes. They are rinsed free of excess materials by dipping briefly in ethanol. Cure of the silane layer is for about 5-10 min. at 110° C. or 24 hours at room temperature (<60% relative humidity).

Deposition from aqueous solution can also be employed. The silane is dissolved at 0.5-2.0% concentration in water. For less soluble silanes, 0.1% of a nonionic surfactant is added prior to the silane and an emulsion rather than a solution is prepared. The solution is adjusted to pH 5.5 with acetic acid. The solution is either sprayed onto the substrate or employed as a dip bath. Cure is at 110-120° C. for 20-30 minutes. Stability of aqueous silane solutions varies from 2-12 hours for the simple alkyl silanes. Poor solubility parameters limit the use of long chain alkyl and aromatic silanes by this method. Distilled water is not necessary, but water containing fluoride ions must be avoided.

It will be appreciated that while the invention has been described in detail and with reference to specific embodiments, numerous modifications and variations are possible without departing from the spirit and scope of the invention as defined by the following claims.

What is claimed is:

1. A conductivity sensor comprising:
a forked electrode support including first and second opposing arms, the arms being spaced apart by a slot therebetween; and
a plurality of electrodes embedded in the first arm and a plurality of electrodes embedded in the second arm;
wherein the first and second arms and the slot are capable of retaining a volume of fluid within the volume defined by the arms and the slot such that the conductivity of the fluid in the slot can be determined.

2. The conductivity sensor of claim 1 further comprising:
a reciprocating or rotating wiper assembly including a wiper element, the wiper assembly positioned adjacent the electrode support such that the wiper element can travel through the slot.

3. The conductivity sensor of claim 2 wherein the wiper element is a brush or an elastomeric pad.

4. The conductivity sensor of claim 2 wherein the wiper assembly includes a rotatable arm connected to the wiper element and connected to a shaft, wherein the rotatable arm rotates on the shaft.

5. The conductivity sensor of claim 1 wherein the slot is about 0.25 cm to about 2.5 cm wide and about 0.64 cm to about 3.8 cm deep.

6. The conductivity sensor of claim 1 wherein the plurality of electrodes in the first arm and the plurality of electrodes in the second arm each comprise a concentric pair of electrodes, wherein one electrode is a drive electrode and the other is a sense electrode.

7. The conductivity sensor of claim 6 wherein the concentric pair of electrodes in the first arm are aligned opposite the concentric pair of electrodes in the second arm.

8. The conductivity sensor of claim 1 wherein the slot includes a floor, wherein the floor is contoured to enhance the removal of bubbles from the slot.

9. The conductivity sensor of claim 8 wherein the floor has an apex and the apex is centered under the first and the second electrodes, an apex off-center relative to the first and the second electrodes, has a rounded crest, or is an inclined plane.

10. The conductivity sensor of claim 1 further comprising a temperature probe disposed within the slot.

11. A wipeable conductivity sensor assembly comprising:
a conductivity sensor comprising:
a forked electrode support including first and second opposing arms, the arms being spaced apart by a slot therebetween; and
a plurality of electrodes in the first arm and a plurality of electrodes in the second arm;
wherein the first and second arms and the slot are capable of retaining a volume of fluid within the volume defined by the arms and the slot such that the conductivity of the fluid in the slot can be determined; and
a reciprocating wiper assembly including a wiper element, the wiper assembly positioned adjacent the electrode support such that the wiper element can travel through the slot.

12. The conductivity sensor assembly of claim 11 wherein the wiper element is a brush or an elastomeric pad.

13. The conductivity sensor assembly of claim 11 wherein the wiper assembly includes a rotatable arm connected to the wiper element and connected to a shaft, wherein the rotatable arm rotates on the shaft.

14. The conductivity sensor assembly of claim 11 wherein the slot is about 0.25 cm to about 2.5 cm wide and about 0.64 cm to about 3.8 cm deep.

15. The conductivity sensor of claim 11 wherein the plurality of electrodes in the first arm and the plurality of electrodes in the second arm each comprise a concentric pair of electrodes, wherein one electrode is a drive electrode and the other is a sense electrode.

16. The conductivity sensor of claim 15 wherein the concentric pair of electrodes in the first arm are aligned opposite the concentric pair of electrodes in the second arm.

17. The conductivity sensor of claim 11 wherein the slot includes a floor, wherein the floor is contoured to enhance the removal of bubbles from the slot.

18. The conductivity sensor of claim 17 wherein the floor has an apex centered under the first and the second electrodes, an apex off-center relative to the first and the second electrodes, has a rounded crest, or is an inclined plane.

19. The conductivity sensor of claim 11 further comprising a temperature probe disposed within the slot.

20. A process for manufacturing an electrode support of a conductivity sensor, the process comprising:
providing a preform electrode element that is machineable into a first and a second set of concentric electrodes that each comprise at least two electrodes separated from one another by a gap to electrically insulate the electrodes;
encasing the preform electrode element in an electrically insulating material to form an encased preform electrode body; and
forming a slot in the encased preform electrode body by removing a portion of the plastic or ceramic material and a portion of the preform electrode element,
wherein the slot defines a cell portion within the encased preform electrode body, wherein the cell portion includes a first wall having a first set of concentric electrodes and a second wall having a second set of concentric electrodes, wherein the first and second sets of concentric electrodes are aligned opposite one another.

21. The process of claim 20 further comprising polishing at least the first and second set of concentric electrodes.

22. The process of claim 20 further comprising surrounding at least the length of the encased preform electrode body with a casing.

23. The process of claim 22 wherein the casing is a metal or metal alloy.

24. The process of claim 23 further comprising silanizing the metal or metal alloy prior to the step of surrounding at least the length of the encased preform electrode body with a casing.

25. The process of claim 20 further comprising providing an outer housing for the encased preform electrode body, and wherein encasing the preform electrode element includes placing the preform electrode element in the outer housing and filling the outer housing with the electrically insulating material to integrally mold the preform electrode element and the electrically insulating material to the outer housing.

26. The process of claim 25 further comprising:
silanizing the outer housing with a silane coupling agent before encasing the preform electrode element.

27. The process of claim 26 wherein the outer housing is titanium.

28. The process of claim 20 wherein the electrically insulating material is a plastic, ceramic, or resin.

29. The process of claim 28 wherein the plastic is a glass-filled imide.

30. The process of claim 20 further comprising:
providing a connecting ring to form the base of the electrode support; and
wherein the electrically insulating material is plastic, and the encasing step also includes molding the plastic to the connecting ring.

31. The process of claim 30 wherein the molding step includes over-molding the plastic at least partially onto the connecting ring.

32. The process of claim 30 wherein the connecting ring is metal, and the process further comprises silanizing at least the portion of the connecting ring that is molded to the plastic prior to encasing the preform electrode in the plastic.

33. The process of claim 32 wherein the connecting ring is titanium and the plastic is a glass-filled imide.

34. The process of claim 20 further comprising silanizing the preform electrode element prior to encasing it in the electrically insulating material.

35. The process of claim 20 wherein the electrically insulating material is a thermoplastic material.

36. The process of claim 35 wherein the thermoplastic material is a glass-filled polyimide.

37. The process of claim 20 wherein the preform electrode element includes at least one of a titanium, nickle, a nickle alloy, graphite, graphite-impregnated resins, and graphite-impregnated plastics.

38. The process of claim 20 wherein the electrical insulating material is a body including ceramic material, the body having a bore extending therethrough, and wherein the step of encasing includes applying a sealing glass to the external surfaces of the preform electrode element and assembling it into the bore and filling the gap between the electrodes in each set of concentric electrodes with the sealing glass, and heating the assembly to bond the preform electrode to the ceramic material.

39. The process of claim 38 further comprising connecting leads to the electrodes and electrically insulating the leads from one another.

40. The process of claim 38 further comprising surrounding at least the length of the encased preform electrode body with an outer housing.

41. The process of claim 20 wherein the gap between the electrodes in both of the first and the second set of concentric electrodes extends uniformly from the slot toward the periphery of the encased preform electrode body.

42. The process of claim 20 wherein the gap between the electrodes in both of the first and the second set of concentric electrodes gradually tapers as it extends from the slot toward the periphery of the encased preform electrode body.

43. The process of claim 42 wherein the gap is generally conical.

44. A process for manufacturing an electrode support for a conductivity sensor comprising:
providing a first set of concentric electrodes and a second set of concentric electrodes;
providing a forked electrode support including first and second opposing arms spaced apart to provide a slot therebetween, wherein the first opposing arm includes a first receptacle for receiving the first set of concentric electrodes and the second opposing arm includes a second receptacle for receiving the second set of concentric electrodes;
placing the first and the second set of concentric electrodes into their respective receptacles; and
bonding the forked electrode support to each of the first and the second set of concentric electrodes with a watertight seal.

45. The process of claim 44 wherein the forked electrode support is a ceramic material.

46. The process of claim 45 further comprising applying sealing glass to the outer surface of the outer most electrode and between the electrodes of each set of concentric electrodes to seal the electrodes to one another and to the ceramic body.

47. The process of claim 45 wherein the bonding includes heating the sealing glass.
